(19) United States
(12) Patent Application Publication
(10) Pub. No.: US 2019/0326276 A1
(43) Pub. Date: Oct. 24, 2019

(54) CIRCUIT OF PROTECTION AGAINST ELECTROSTATIC DISCHARGES

(71) Applicant: STMicroelectronics (Tours) SAS, Tours (FR)

(72) Inventor: Mathieu ROUVIERE, Tours (FR)

(73) Assignee: STMicroelectronics (Tours) SAS, Tours (FR)

(21) Appl. No.: 16/388,191

(22) Filed: Apr. 18, 2019

(30) Foreign Application Priority Data
Apr. 20, 2018 (FR) 1853500

(51) Int. Cl. H01L 27/02; H01L 29/866

(52) U.S. Cl. CPC H01L 27/0262; H01L 29/866; H01L 27/0255

(57) ABSTRACT

An electrostatic discharge protection circuit includes a diode bridge in parallel with a thyristor and a first avalanche diode. The diode bridge is coupled between first and second nodes. The thyristor has an anode coupled to the first node and a cathode coupled to the second node. The first avalanche diode has a cathode coupled to the first node and an anode coupled to the second node. A second avalanche diode has a cathode coupled to the first node and an anode coupled to a gate of the thyristor. When an electrostatic discharge occurs, current flows through the diode bridge, into the first node, and is first dissipated by the avalanche diode and is thereafter also dissipated by the thyristor once the thyristor turns on.

### PRIORITY CLAIM

This application claims the priority benefit of French Application for Patent No. 1853500, filed on Apr. 20, 2018, the content of which is hereby incorporated by reference in its entirety to the maximum extent allowable by law.

### TECHNICAL FIELD

The present disclosure concerns a circuit for protection against electrostatic discharges, and more particularly a circuit for protection against electrostatic discharges that is capable of protecting input/output nodes of an electronic circuit.

### BACKGROUND

Issues relating to electrostatic discharges are all the more present now as electronic circuit components are smaller and smaller and closer and closer to one another. The protection of electronic circuits against electrostatic discharges is important to help ensure the reliability and the durability of such electronic circuits.

There thus is a permanent need for electrostatic discharge protection circuits having better performance.

### SUMMARY

An embodiment provides a circuit for protection against electrostatic discharges including, in parallel, a thyristor and a first avalanche diode.

According to an embodiment, the anode and the cathode of the thyristor are respectively directly connected to the anode and to the cathode of the first avalanche diode.

According to an embodiment, the anode of the thyristor and the anode of the first avalanche diode are connected to a first node and the cathode of the thyristor and the cathode of the first avalanche diode are connected to a second node.

According to an embodiment, the thyristor has an anode gate coupled to a cathode of a second avalanche diode.

According to an embodiment, the second avalanche diode has an anode connected to the second node.

According to an embodiment, the circuit also includes a diode bridge.

According to an embodiment, the diode bridge has at least two input nodes and two output nodes.

According to an embodiment, the output nodes are the first and second nodes.

According to an embodiment, each input node is coupled to an input/output node of an electronic circuit to be protected.

According to an embodiment, each input/output node provides an AC voltage.

### BRIEF DESCRIPTION OF THE DRAWINGS

The foregoing and other features and advantages will be discussed in detail in the following non-limiting description of specific embodiments in connection with the accompanying drawings, wherein:

FIG. 1 is a schematic diagram of an embodiment of a circuit for protection against electrostatic discharges; and

FIG. 2 illustrates the behavior of the circuit of FIG. 1 upon occurrence of an electrostatic discharge.

### DETAILED DESCRIPTION

The same elements have been designated with the same reference numerals in the different drawings. For clarity, only those steps and elements which are useful to the understanding of the described embodiments have been shown and are detailed.

Unless otherwise specified, the terms “approximately”, “substantially”, “about”, and “in the order of” are used herein to designate a tolerance of plus or minus 10%, preferably of plus or minus 5%, of the value in question.

In the present description, the term “connected” will be used to designate a direct electric connection, with no intermediate electronic component, for example, by means of a conductive track, and the term “coupled” or term “linked” will be used to designate either a direct electric connection (then meaning “connected”) or a connection via one or a plurality of intermediate components (resistor, capacitor, etc.).

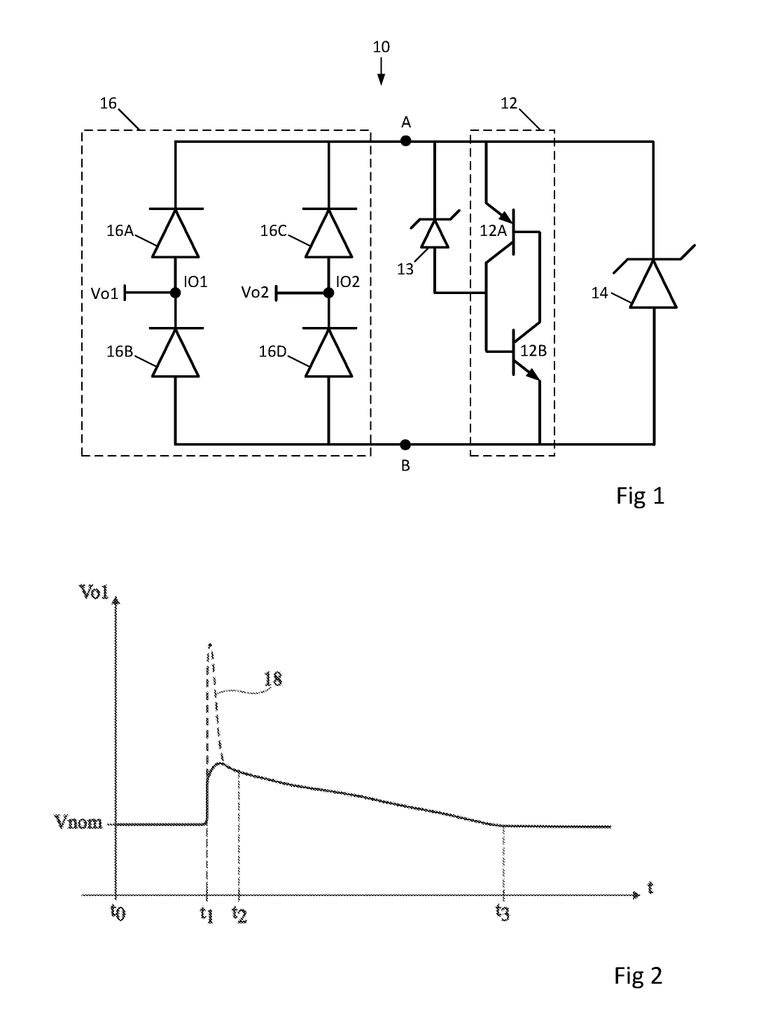

FIG. 1 is an electric diagram of an embodiment of a circuit for protection against electrostatic discharges 10.

Circuit 10 comprises a thyristor 12, shown in FIG. 1 by a PNP-type bipolar transistor 12A and an NPN-type bipolar transistor 12B connected to each other. The collector of transistor 12A is coupled, preferably connected, to the base of transistor 12B, and the collector of transistor 12B is coupled, preferably connected, to the base of transistor 12A. Thyristor 12 connects a node A to a node B. More particularly, the anode of thyristor 12 is connected to node A and the cathode of thyristor 12 is connected to node B. In other words, the emitter of transistor 12A is connected to node A and the emitter of transistor 12B is connected to node B. The gate of thyristor 12 is formed by the base of transistor 12B and is coupled to node A via an avalanche diode 13. More particularly, the anode of diode 13 is coupled, preferably connected, to the base of transistor 12B and its cathode is coupled, preferably connected, to node A.

Circuit 10 further comprises an avalanche diode 14, or Zener diode, in parallel with thyristor 12. More particularly, the cathode of diode 14 is connected to node A and its anode is connected to node B.

Circuit 10 further comprises a diode bridge 16 having two input nodes IO1 and IO2 and having as output nodes the two nodes A and B. Diode bridge 16 comprises four diodes 16A, 16B, 16C, and 16D. Diodes 16A and 16B are series-connected between nodes A and B. More particularly, the cathode of diode 16A is coupled, preferably connected, to node A, and the anode of diode 16A is coupled, preferably connected, to node IO1. The cathode of diode 16B is coupled, preferably connected, to node IO1, and the anode of diode 16B is coupled, preferably connected, to node B. Diodes 16C and 16B are series-connected between nodes A and B. More particularly, the cathode of diode 16C is coupled, preferably connected, to node A, and the anode of diode 16C is coupled, preferably connected, to node IO2. The cathode of diode 16D is coupled, preferably connected, to node IO2, and the anode of diode 16D is coupled, preferably connected, to node B.

The circuit 10 illustrated in FIG. 1 is a circuit for protection against electrostatic discharges capable of protecting two input/output nodes of an electronic circuit. Each input node IO1, IO2 is capable of being connected to one of the input/output nodes of the circuit to be protected. According to an alternative embodiment, circuit 10 could be adapted to protect N input/output nodes. In this case, diode bridge 16 would comprise 2*N diodes and N input nodes, and each pair of diodes would be arranged around a node in the same way as diodes 16A and 16B are arranged around node IO1.

Nodes IO1 and IO2 thus receive supply voltages Vo1 and Vo2 of input/output nodes of an electronic circuit. Voltages Vo1, Vo2 are for example AC voltages. Diode bridge 16, having low junction capacitance values, enable masking the greater junction capacitances of thyristor 12 and of diodes 13 and 14.

The operation of circuit 10 in the presence of an overvoltage is explained in relation with FIG. 2.

FIG. 2 is a timing diagram for example illustrating the variation of voltage Vo1 of node IO1 when a positive electrostatic discharge reaches the input/output node of the electronic circuit coupled to node IO1.

Between a time t0 and a time t1, voltage Vo1 is at a stable level Vnom.

At time t1, an electrostatic discharge reaches the input/output node connected to node IO1 of circuit 10. Avalanche diode 14 breaks down and dissipates a portion of the discharge. Diode 14 limits or avoids a first overvoltage peak 18 (in dotted lines in FIG. 2).

At a time t2 (for example, a few nanoseconds after t1), thyristor 12 is totally turned on and dissipates the rest of the discharge. Thyristor 12 enables holding a clipped potential.

At a time t3, protection circuit 10 has dissipated all the energy of the electrostatic discharge and voltage Vo1 has returned to level Vnom.

An advantage of this embodiment is that, without the avalanche diode 14, thyristor 12 would give way to overvoltage peak 18, formed by the electrostatic discharge before time t₂. Indeed, the first PN junction of the thyristor would start conducting and would give way to overvoltage peak 18 rather than dissipate it.

In the circuit of FIG. 1, avalanche diode 14 breaks down on occurrence of the electrostatic discharge (time t₁) and dissipates overvoltage peak 18. As an example, the addition of diode 14 may enable attenuation of the amplitude of a peak 18 which may reach from more than 100 V, for example, approximately 115 V, to some sixty volts, for example, approximately 64 V.

An advantage of this embodiment is that the presence of diode 14, having a lower residual voltage than the residual voltage of thyristor 12, enables more efficient dissipation of the voltage peak 18 of FIG. 2, which is not dissipated by thyristor 12. As an example, doubling the surface area of diode 14 in parallel with thyristor 12 enables decreasing a first peak of approximately 115 V down to a peak of approximately 57 V.

Specific embodiments have been described. It should be noted that those skilled in the art may combine various elements of these various embodiments and variations without showing any inventive step.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A circuit for protection against electrostatic discharges, comprising, a thyristor and a first avalanche diode that are connected in parallel with each other.

2. The circuit of claim 1, wherein an anode of the thyristor is directly connected to a cathode of the first avalanche diode and wherein a cathode of the thyristor is respectively directly connected to an anode of the first avalanche diode.

3. The circuit of claim 2, wherein the anode of the thyristor and the cathode of the first avalanche diode are connected to a first node and the cathode of the thyristor and the anode of the first avalanche diode are connected to a second node.

4. The circuit of claim 3, wherein the thyristor has a cathode gate coupled to an anode of a second avalanche diode.

5. The circuit of claim 4, wherein the second avalanche diode has a cathode connected to the first node.

6. The circuit of claim 3, further comprising a diode bridge coupled between the first and second nodes.

7. The circuit of claim 6, wherein the diode bridge comprises at least two input nodes and two output nodes.

8. The circuit of claim 7, wherein the output nodes are the first and second nodes.

9. The circuit of claim 7, wherein each input node is coupled to an input/output node of an electronic circuit to be protected.

10. The circuit of claim 9, wherein each input/output node supplies an AC voltage.

11. A circuit, comprising:
a diode bridge;
a clamping circuit coupled in parallel with the diode bridge; and
an avalanche diode coupled in parallel with the clamping circuit.

12. The circuit of claim 11, wherein the clamping circuit comprises a thyristor.

13. The circuit of claim 11, wherein the diode bridge is coupled between first and second nodes; wherein the thyristor has an anode connected to the first node and a cathode connected to the second node; and wherein the avalanche diode has a cathode connected to the first node and an anode connected to the second node.

14. The circuit of claim 13, further comprising a second avalanche diode having a cathode connected to the first node and an anode connected to a gate of the thyristor.

15. The circuit of claim 13, wherein the diode bridge comprises:
a first diode having a cathode coupled to the first node and an anode coupled to a first input;
a second diode having a cathode coupled to the first input and an anode coupled to the second node;
a third diode having a cathode coupled to the first node and an anode coupled to a second input; and
a fourth diode having a cathode coupled to the second input and an anode coupled to the second node.

16. A circuit, comprising:
a thyristor having a first conduction terminal coupled to a first node, a second conduction terminal coupled to a second node, and a control terminal;
a first avalanche diode having a cathode coupled to the first node and an anode coupled to the second node; and
a second avalanche diode having a cathode coupled to the first node and an anode coupled to the control terminal of the thyristor.

17. The circuit of claim 16, wherein the first conduction terminal of the thyristor is an anode and wherein the second conduction terminal of the thyristor is a cathode.
